(19) United States
(12) Patent Application Publication
(10) Pub. No.: US 2005/0016746 A1
(43) Pub. Date: Jan. 27, 2005

(54) Ground shield structure

(76) Inventors: Bouryi Sze, Hsin-Tien City (TW); Bob Cheng, Hsin-Tien City (TW); Chih-Long Ho, Hsin-Tien City (TW); Felix Kao, Hsin-Tien City (TW)

Correspondence Address: J C PATENTS, INC., 4 VENTURE, SUITE 250, IRVINE, CA, 92618, US

(21) Appl. No.: 10/681,471

(22) Filed: Oct. 7, 2003

(30) Foreign Application Priority Data
Jul. 21, 2003 (TW) 92213288

(51) Int. Cl. H05K 9/00

(52) U.S. Cl. 174/35 R

(57) ABSTRACT

A ground shield structure is suitable for use in a circuit structure. The ground shield structure has a plurality of ground cells that are arranged on a ground plane periodically, compactly and complementarily. The slots between the ground cells are used to reduce the eddy current generated on the ground shield structure. The ground shield structure increases the slow-wave factor to slow the waves so that the area of the circuit layout can be decreased. Besides, the ground shield structure can reduce the energy loss of the inner circuit of the circuit structure and can increase the quantities of inductance and capacitance in per unit area thereon.

### CROSS-REFERENCE TO RELATED APPLICATION

This application claims the priority benefit of Taiwan application serial no. 92213288, filed Jul. 21, 2003.

### BACKGROUND OF THE INVENTION

1. Field of Invention

The present invention relates to a ground shield structure. More particularly, the present invention relates to a compact and complementary ground shield structure (CCGSS) by a periodic arrangement.

2. Description of Related Art

In recent years, electronic techniques have been greatly and promptly developed. Particularly, since the semiconductor fabrication has been greatly developed, the integration for an integrated circuit (IC) device is continuously improved. Then, the size of an IC device is greatly reduced. Similarly, since the integration of an IC device is continuously improved, a circuit module, which usually is composed of several IC devices, can be formed by a single IC chip. In this manner, the function of the electronic product can be more and more powerful. Furthermore, the volume and the weight is more and more reduced.

In order to satisfy the circuit design for an IC device, and an inductor is necessary to be formed in the IC chip, the conventional technology is using the internal circuit of the IC chip to directly form the solenoid-like inductance coil, which is implemented over a substrate. As a result, when the current flows through the inductance coil, due to the flow of the current, an inducted current is generated. At the same time, the inducted current causes an eddy current on the substrate. It should be noted that occurrence of the eddy current then relatively decreases the inductance from the inductance coil.

In order to reduce the generation of eddy current, the conventional technology proposes a patterned ground shield (PGS) structure. FIG. 1 is a drawing, schematically illustrating the conventional ground shield structure. In FIG. 1, since several slots 120 of the ground shield structure 100 are used to divide the ground shield structure 100 into several ground strips 110. The ground strips 110 take a center point for reference, and are usually bent by an angle, such as 90 degrees, and then are disposed on the ground plane by a substantial irradiating arrangement. The conductive vias or other connecting pieces are used for electric connection. Moreover, since the slots 120 are designed to be very narrow, the electric field does not leak through the slots 120 to the region under the ground shield structure 100. The ground strips 110 are then used as the termination of the electric field.

It should be noted that since the slots 120 forms several open circuits in the ground shield structure 100, when an inductance coil (not shown) over the ground shield structure 100 is applied with a current, and the eddy current occurs on the ground shield structure 100, the slot 120 on the flow path of the eddy current E on the ground shield structure 100 can effectively cut the eddy current E. It can be reduced for the effect from decreasing the inductance quantity on the inductance coil due to the eddy current E. However, with respect to the ground shield structure 100, the ground strips 110 take a center point for reference, and are usually bent by an angle, such as 90 degrees, and then are arranged on the ground plane by a substantial irradiating arrangement. The foregoing ground shield structure 100 can only be used to remove the eddy current E, which is generated due to the inducting current on the ground shield structure 100. It cannot serve as the ground shield for the other microwave transmission device, such as transmission line, wave-guide, power divider, directional coupler, or microwave filter.

### SUMMARY OF THE INVENTION

The invention provides a ground shield structure, suitable for use of cutting the eddy current that is caused by the inducted current on the ground shield structure.

The invention provides a ground shield structure, suitable for use of increasing the slow-wave factor, so that the wave can slowly propagate and the needed area for the circuit layout is effectively reduced.

The invention further provides a ground shield structure, for increasing the inductance quantity and capacitance quantity of the ground shield structure in a unit area.

For at least achieving the foregoing objectives, the invention further provides a ground shield structure, suitable for use in a circuit structure. The ground shield structure includes multiple ground cells, which are distributed on a ground surface by a periodic and compactly complementary arrangement. A slot exists between two adjacent ground cells

In accordance with the foregoing features, the ground shield structure is suitable for use in a circuit structure. The ground shield structure has a plurality of ground cells that are arranged on a ground plane periodically, compactly and complementarily. The slots between the ground cells are used to reduce the eddy current generated on the ground shield structure. The ground shield structure increases the slow-wave factor to slow the waves so that the area of the circuit layout can be decreased. Besides, the ground shield structure can reduce the energy loss of the inner circuit of the circuit structure and can increase the quantities of inductance and capacitance in per unit area thereon.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a drawing, schematically illustrating the conventional ground shield structure.

FIGS. 2A-2D are drawings, schematically illustrating four different ground shield structures, according to preferred embodiments of this invention.

FIG. 3 is a drawing, schematically illustrating a fifth different ground shield structure, according to another preferred embodiment of this invention.

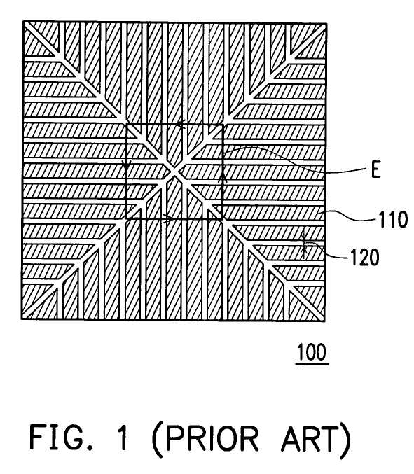

### DESCRIPTION OF THE PREFERRED EMBODIMENTS

The ground shield structure of the invention is suitable for use in a circuit structure, such as an integrated circuit, a printed circuit board, a chip package substrate, or other electronic devices, so as to provide the shielding function.

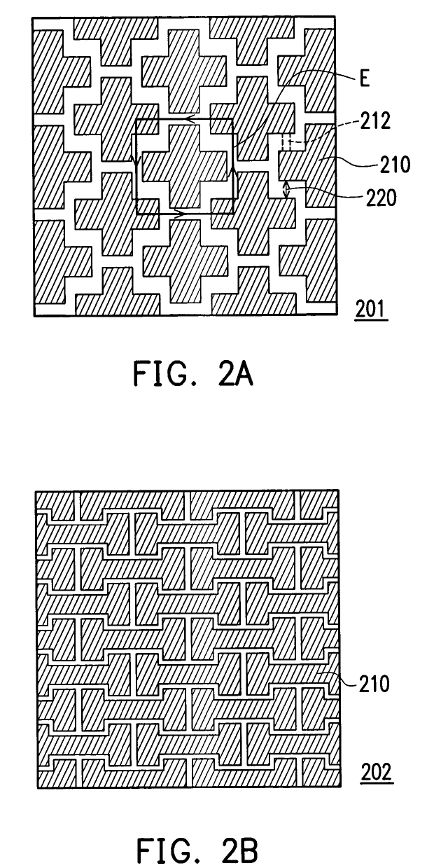

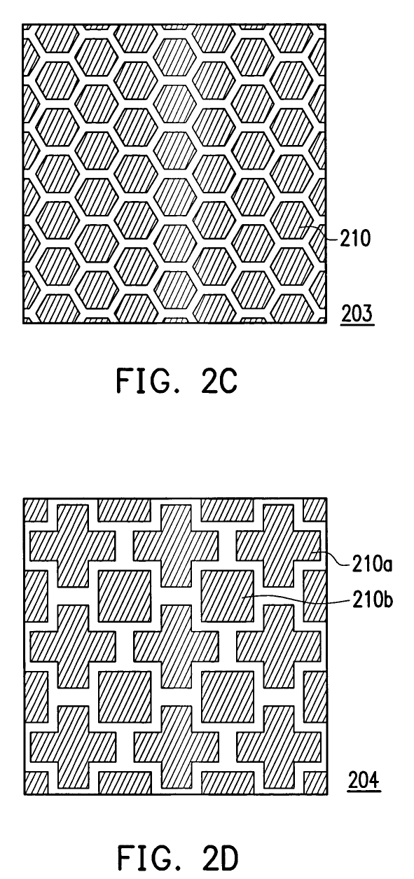

In FIG. 2A, a ground shield structure is shown, according to the invention. The ground shield structure 201 includes several ground cells 210, with identical profile, like a symbol of “+”. The ground cells 210 are distributed on a ground surface with a periodically and compactly complementary arrangement, wherein a slot 220 exists between two adjacent ground cells 210. It should be noted that the ground surface with the ground cells 210 is not limited to a planar surface. A curved surface is also applicable.

In addition, in order to electrically connect with the ground cells 210 and allow the ground cells 210 to be able to form a ground shield, the ground shield structure 201 further includes several interconnection members 212 (only one is shown by dashed line). The interconnection members 212 are respectively coupled between two adjacent ground cells 210. Moreover, when the ground shield structure 201 is formed by one of multiple circuit layers of the circuit structure, the vias in the circuit layers can be further used for connecting to the ground cells 210. As a result, the ground cells 210 can be indirectly and electrically coupled together through the circuit layers.

When the ground shield structure 201 is located under an inducted circuit (not shown), the current flowing through the inducting circuit would generated the inducted current. Accordingly, an eddy current E occurs on the ground shield structure 201 under the inducting circuit. However, in order to prevent the eddy current from occurring, the slot 220 on the flowing path of the eddy current E of the ground shield structure 201 can effectively cut the eddy current E. Then the affection on the inductance quantity of the inducting circuit from the eddy current E can be reduced. Further still, sine the slots 220 are designed to be very narrow, the electric field on the ground shield structure does not leak to the bottom region of the ground shield structure 201 through the slots 220. The ground cells 210 are used as the termination of the electric filed.

In FIGS. 2B-2D, they are drawings, schematically illustrating four different ground shield structures, according to preferred embodiments of this invention. In addition to the “+” shape of FIG. 2A for the ground cells 210, FIG. 2B shows another ground shield structure 202. The shape of the ground cells 210 in profile can be a dumbbell shape. Further in FIG. 2C, the ground shield structure 203 is shown. The cross-sectional profile of the ground cell 210 can also be like the beehive, that is a right hexagon. In addition to the ground cells 210 with a single cross-sectional profile, as shown in FIG. 2D, the ground shield structure 204 can include two or more different cross-section profiles 210a, 210b to be compact and complementary.

The cross-sectional profile of the ground cells of the ground shield structure in the invention include a single shape or multiple shapes as the example. However, under the consideration of periodical and compact arrangement, the ground cells of the ground shield structure in cross-sectional profile can be other shape, such as triangle, rectangle, regular polygon, or irregular polygon.

The ground cells of the ground shield structure in the invention can be formed by a patterning process with the positive manner or the negative manner.

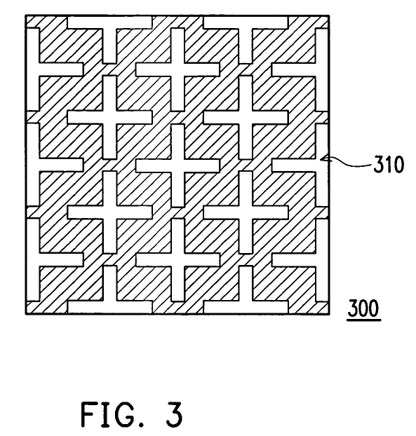

FIG. 3 is a drawing, schematically illustrating a fifth different ground shield structure, according to another preferred embodiment of this invention. In FIG. 3, the ground shield structure 300 can be formed from a ground layer, which has been patterned, wherein a plurality of slots 310 are formed in periodic and regular arrangement. Further still, the in comparison with the ground cells 210 in FIG. 2A, these slots 310 have the identical cross-section profile or different cross-section profiles. However, it is still within the principle of compact and complementary arrangement. In addition, the ground shield structure 300 itself, that is, a ground surface, is not limited to a planar surface. It can be a curved surface, so that the ground shield structure300 can enclose a transmission line.

The ground shield structures in various embodiments of the invention can be used in a circuit structure, such as an integrated circuit chip, a printed circuit board, or a die carrier in packaging, so as to reduce the area of a signal transmission device, such as transmission line, waveguide structure, power driver, a directional coupler, or microwave filter. As a result, the product quality can be effectively improved. Furthermore, the ground shield structure of the invention can also be used in a small-type electronic device, such as a low temperature ceramic capacitor (LTCC) and so on, so as to provide the ground shield function.

In summary, the ground shield structure of the invention with compact and complementary arrangement at least has several advantages as follows:
1. For the ground shield structure of the invention, the slot between the ground cells can increase the slow-wave factor to slow the waves so that the area of the circuit layout can be decreased.
2. For the ground shield structure of the invention, the ground shield structure can reduce the energy loss of the inner circuit of the circuit structure.
3. For the ground shield structure of the invention, it can increase the quantities of inductance and capacitance in per unit area thereon.
4. For the ground shield structure of the invention, the ground cells are arranged to be periodic and compactly complementary, so that it can be easily integrated into the integrated circuit chip, the printed circuit board, the die carrier in packaging, without the addition fabrication process.

It will be apparent to those skilled in the art that various modifications and variations can be made to the structure of the present invention without departing from the scope or spirit of the invention. In view of the foregoing, it is intended that the present invention covers modifications and variations of this invention provided they fall within the scope of the following claims and their equivalents.

1. A ground shield structure, suitable for use in an electronic circuit structure, the ground shield structure at least comprising:
a plurality of multi-edge ground cells, periodically, compactly, and complementarily distributed on a ground surface, wherein a slot exists between the two adjacent ground cells.

2. The ground shield structure of claim 1, further comprising at least an interconnection member connecting two of the adjacent ground cells.

3. The ground shield structure of claim 1, wherein the ground cells have an identical cross-sectional profile.

4. The ground shield structure of claim 1, wherein the ground cells have different shape of cross-sectional profiles.

5. The ground shield structure of claim 1, wherein the ground surface includes a planar surface.

6. The ground shield structure of claim 1, wherein the ground surface includes a curved surface.

7. A ground shield structure, suitable for use in an electronic circuit structure, the ground shield structure at least comprising:
a ground surface, comprising a plurality of slots in a multi-edge shape, the slots are distributed in the ground surface by a periodic, compact and complementary arrangernent.

8. The ground shield structure of claim 7, wherein the slots have an identical cross-sectional profile.

9. The ground shield structure of claim 7, wherein the slots have different cross-sectional profiles.

10. The ground shield structure of claim 7, wherein the ground surface includes a planar surface.

11. The ground shield structure of claim 7, wherein the ground surface includes a curved surface.

12. A ground shield structure, suitable for use in an electronic circuit structure, the ground shield structure at least comprising:
a ground surface, comprising a plurality of multi-edge ground cells, distributed on the ground surface by a periodic, compact and complementary arrangement.

13. The ground shield structure of claim 12, wherein the multi-edge ground cells are portions of the ground surface.

14. The ground shield structure of claim 13, further comprising at least an interconnection member connecting two of the adjacent ground cells.

15. The ground shield structure of claim 12, wherein the multi-edge ground cells are slots of the ground surface.

16. The ground shield structure of claim 12, wherein the multi-edge ground cells have an identical cross-sectional profile.

17. The ground shield structure of claim 12, wherein the multi-edge ground cells have different cross-sectional profiles.

18. The ground shield structure of claim 12, wherein the ground surface includes a planar surface.

19. The ground shield structure of claim 12, wherein the ground surface includes a curved surface.

20. The ground shield structure of claim 1, wherein the ground cells includes a shape being “+”-like, dumbbell-like, beehive-like, or mix of “+”-like and rectangular.

21. The ground shield structure of claim 7, wherein the ground cells includes a shape being “+”-like, dumbbell-like, beehive-like.

22. The ground shield structure of claim 12, wherein the ground cells includes a shape being “+”-like, dumbbell-like, beehive-like, or mix of “+”-like and rectangular.
